(19) United States
(12) Patent Application Publication
(10) Pub. No.: US 2024/0128171 A1
(43) Pub. Date: Apr. 18, 2024

(54) METHOD OF MANUFACTURING SEMICONDUCTOR PACKAGE, AND SEMICONDUCTOR PACKAGE

(71) Applicant: SAMSUNG ELECTRONICS CO., LTD., Suwon-si (KR)

(72) Inventors: Junwoo Myung, Suwon-si (KR); Gun Lee, Suwon-si (KR)

(73) Assignee: SAMSUNG ELECTRONICS CO., LTD., Suwon-si (KR)

(21) Appl. No.: 18/204,241

(22) Filed: May 31, 2023

(30) Foreign Application Priority Data
Oct. 12, 2022 (KR) 10-2022-0130414

(51) Int. Cl. H01L 23/498; H01L 21/60; H01L 23/00; H01L 23/14; H01L 23/485; H01L 23/532

(52) U.S. Cl. CPC H01L 23/49816; H01L 21/60; H01L 23/142; H01L 23/485; H01L 23/53228; H01L 24/97; H01L 2021/60255; H01L 2224/97; H01L 2924/15311

(57) ABSTRACT

A method of manufacturing a semiconductor package includes applying a cutter to a boundary between a main portion of a second metal layer and an edge portion of the second metal layer that surrounds the main portion, the second metal layer being on an upper surface of a first metal layer disposed on an upper surface of a carrier substrate, peeling the edge portion of the second metal layer from the first metal layer, forming a cover insulating layer on an upper surface of the main portion of the second metal layer, and disposing a semiconductor chip on an upper surface of the cover insulating layer.

### CROSS-REFERENCE TO RELATED APPLICATION(S)

This application claims priority under 35 USC 119(a) of Korean Patent Application No. 10-2022-0130414 filed on Oct. 12, 2022 in the Korean Intellectual Property Office, the entire disclosure of which is incorporated by reference herein for all purposes.

### BACKGROUND

The present disclosure relates to a method of manufacturing a semiconductor package, and a semiconductor package.

In general, a semiconductor chip may be implemented as a semiconductor package such as a wafer level package (WLP) or a panel level package (PLP), and the semiconductor package may be used as an electronic component of a device.

A process of manufacturing a semiconductor package may be accompanied by a plurality of equipment (e.g., equipment for disposing semiconductor chips, equipment for forming a redistribution layer, and equipment for forming bumps/UBMs). Accordingly, semiconductor packages being manufactured may be accompanied by movement between the equipment. A carrier may be used to move the semiconductor packages between the equipment.

### SUMMARY

It is an aspect to provide a method of manufacturing a semiconductor package, and a semiconductor package, in which a carrier may be implemented to be robust to external structures (e.g., adjacent equipment) and to physical conditions.

According to an aspect of one or more example embodiments, a method of manufacturing a semiconductor package comprises applying a cutter to a boundary between a main portion of a second metal layer and an edge portion of the second metal layer that surrounds the main portion, the second metal layer being on an upper surface of a first metal layer disposed on an upper surface of a carrier substrate; peeling the edge portion of the second metal layer from the first metal layer; forming a cover insulating layer on an upper surface of the main portion of the second metal layer; and disposing a semiconductor chip on an upper surface of the cover insulating layer.

According to another aspect of one or more example embodiments, a method of manufacturing a semiconductor package comprises exposing a portion of a first metal layer by removing an edge portion of a second metal layer that surrounds a main portion of the second metal layer, the second metal layer being on an upper surface of the first metal layer disposed on an upper surface of a carrier substrate; forming a cover insulating layer on an upper surface of the main portion of the second metal layer; and disposing a semiconductor chip on an upper surface of the cover insulating layer, wherein a thickness of the second metal layer is greater than 1 μm and less than 10 μm.

According to yet another aspect of one or more example embodiments, a semiconductor package comprising a semiconductor chip electrically connected to a redistribution layer; and a cover insulating layer disposed on a first surface of the semiconductor chip opposite to a second surface of the semiconductor chip that faces the redistribution layer, wherein the cover insulating layer does not provide an electrical connection path between a facing surface of the cover insulating layer that faces the semiconductor chip and an opposite surface of the cover insulating layer that is opposite to the facing surface, the opposite surface of the cover insulating layer has a protruding structure that surrounds the semiconductor chip from a viewpoint facing the semiconductor chip, and a protruding length of the protruding structure is greater than 1 μm and less than 10 μm.

### BRIEF DESCRIPTION OF DRAWINGS

The above and other aspects will be more clearly understood from the following detailed description, taken in conjunction with the accompanying drawings, in which:

FIG. 1A is a cross-sectional view illustrating applying a cutter to a second metal layer in a method of manufacturing a semiconductor package according to some example embodiments;

FIGS. 1B and 1C are cross-sectional views illustrating peeling of an edge portion of a second metal layer in a method of manufacturing a semiconductor package according to some example embodiments;

FIG. 1D is a cross-sectional view illustrating forming a cover insulating layer in a method of manufacturing a semiconductor package according to some example embodiments;

FIG. 2A is a cross-sectional view and a plan view illustrating a method of manufacturing a semiconductor package according to some example embodiments;

FIG. 2B is a cross-sectional view and a plan view illustrating disposing of a semiconductor chip in a method of manufacturing a semiconductor package according to some example embodiments;

FIGS. 3A to 3D are cross-sectional views illustrating a method of manufacturing a semiconductor package according to some example embodiments in more detail; and

FIGS. 4A and 4C are cross-sectional views illustrating a semiconductor package according to some example embodiments.

### DETAILED DESCRIPTION

The detailed description refers to the accompanying drawings which, by way of example, illustrate specific embodiments in which the present disclosure may be practiced. These embodiments are described in sufficient detail to enable one skilled in the art to practice the embodiments. It should be understood that the various embodiments are different from each other but are not necessarily mutually exclusive. For example, one embodiment of specific shapes, structures, and characteristics described herein may be implemented in another embodiment without departing from the spirit and scope of the present disclosure. Additionally, it should be understood that the location or arrangement of individual components within each disclosed embodiment may be changed without departing from the spirit and scope of the present disclosure. Accordingly, the detailed description set forth below is not intended to be taken in a limiting sense, and the scope of the present disclosure is limited only by the appended claims, with all equivalents as claimed by those claims. Like reference numbers in the drawings indicate the same or similar function throughout the various aspects.

A semiconductor package may include a redistribution layer for electrically connecting a semiconductor chip to a device or a printed circuit board. The redistribution layer may have a structure in which redistributions implemented finer than wirings of a wiring layer of a general printed circuit board are extended horizontally.

The redistribution layer may be electrically connected to bumps to vertically extend the electrical connection path, and Under Bump Metallurgy (UBM) may improve electrical connection efficiency between the redistribution layer and bumps.

As described above, a process of manufacturing a semiconductor package may be accompanied by a plurality of equipment (e.g., equipment for disposing semiconductor chips, equipment for forming a redistribution layer, and equipment for forming bumps/UBMs). Accordingly, semiconductor packages being manufactured may be accompanied by movement between equipment. A carrier may be used to move the semiconductor packages between the equipment, and the carrier may be disposed on the upper or lower surface of the semiconductor package being manufactured.

Hereinafter, various embodiments will be described in detail with reference to the accompanying drawings such that those skilled in the art may easily practice the present disclosure.

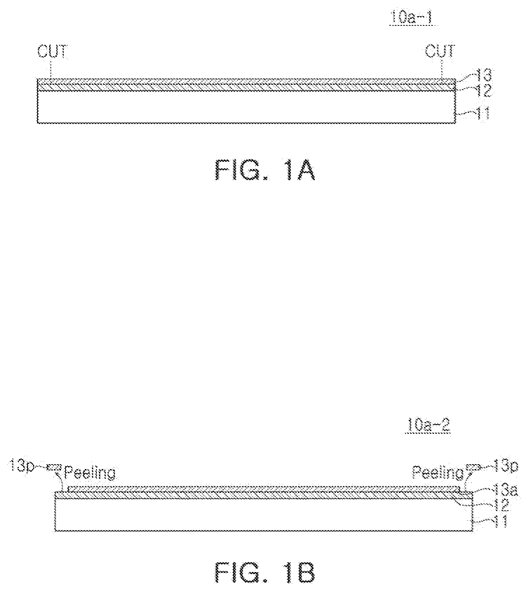

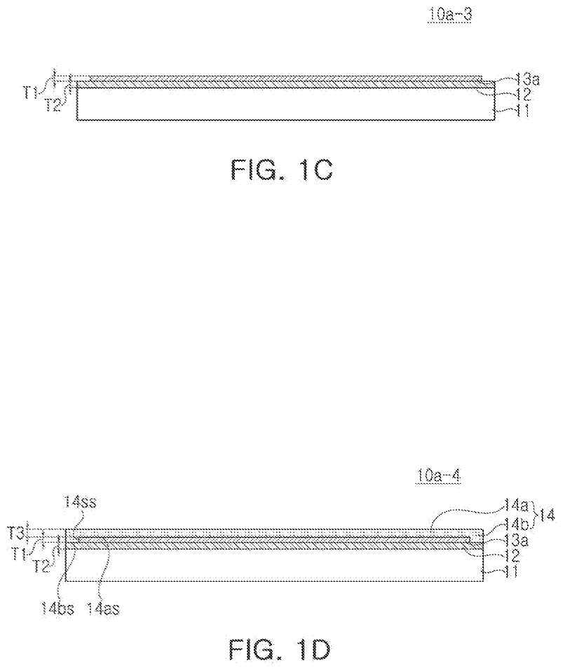

Referring to FIGS. 1A, 1B, and 1C, a method of manufacturing a semiconductor package according to some example embodiments may include an operation 10a-1 of applying a cutter (CUT) on a boundary between an edge portion 13p of a second metal layer 13 and a main portion 13a thereof, where the edge portion 13p surrounds the main portion 13a. The method further comprises an operation 10a-2 of peeling the edge portion 13p of the second metal layer from a first metal layer 12. Accordingly, the edge portion 13p may be excluded from a carrier 10a-3, and a portion of the first metal layer 12 may be exposed upward. The second metal layer 13 is disposed on an upper surface of the first metal layer 12, and the first metal layer 12 is disposed on an upper surface of a carrier substrate 11.

Accordingly, even if an external structure (e.g., adjacent equipment) contacts the side surface of the carrier 10a-3, the external structure may not contact the side surface of the second metal layer 13. That is, the external structure may be prevented from contacting the side surface of the second metal layer 13 due to the excluded portion 13p. Therefore, the adhesiveness between the first metal layer 12 and the second metal layer 13 may be stably maintained, and the carrier 10a-3 may be implemented to be robust to physical conditions and/or to external structures (e.g., adjacent equipment).

Since the carrier substrate 11 may be excluded from the finished semiconductor package, the first metal layer 12 and the second metal layer 13 may be bonded to each other such that the carrier substrate 11 may be easily removed. For example, an organic release layer about 20 nm thick may be disposed between the first and second metal layers 12 and 13 as an adhesive between the first and second metal layers 12 and 13. For example, each of the first and second metal layers 12 and 13 may be a single metal layer containing copper.

Therefore, when the main portion 13a and the edge portion 13p of the second metal layer 13 are separated from each other by the cutter CUT, the edge portion 13p may be excluded from the carrier 10a-3 without photolithography. In detail, the peeling operation (10a-2) may include detaching the edge portion 13p of the second metal layer in a method different from the photolithography method.

For example, in some embodiments, the peeling operation (10a-2) may include pulling the edge portion 13p of the second metal layer from the first metal layer 12. In some embodiments, the peeling operation (10a-2) may include pulling the edge portion 13p of the second metal layer from the first metal layer 12 in a direction (e.g., a horizontal direction and/or an upward direction) different from a direction facing the first metal layer 12 (e.g., a downward direction). In some embodiments, the peeling operation (10a-2) may include pulling the edge portion 13p of the second metal layer from the first metal layer 12 by applying a force to the edge portion 13p of the second metal layer. For example, in some embodiments, one of the equipment for performing the semiconductor package manufacturing method may include a structure attached to the edge portion 13p of the second metal layer, such as a jig, and the structure may receive an upwardly moving force from one of the devices while attached to the edge portion 13p of the second metal layer. In some embodiments, the structure may collide with or apply stress to the side of the edge portion 13p of the second metal layer. Accordingly, the edge portion 13p of the second metal layer may be peeled off without photolithography.

In some embodiments, the cutter (CUT) may be a laser. For example, the operation 10a-1 of applying the cutter (CUT) may include irradiating the laser onto the boundary between the main portion 13a and the edge portion 13p. The laser irradiation time may be set to a time adjusted such that the first metal layer 12 is not divided into a plurality of parts by the cutter (CUT). In other words, in some embodiments, only the second metal layer 13 may be cut and not the first metal layer.

For example, the carrier 10a-3 may be a Detachable Copper Foil (DCF) carrier. In this case, the carrier substrate 11 may contain prepreg. The DCF carrier may be advantageous in reducing the possibility of warpage of a semiconductor package being manufactured. Reducing the possibility of distortion of the semiconductor package may be more important when the horizontal size of the semiconductor package is relatively larger, such as a fan-out panel level package (FO-PLP).

Referring to FIG. 1D, a method of manufacturing a semiconductor package according to some example embodiments may include forming a cover insulating layer 14 on an upper surface 14as of the main portion 13a of the second metal layer.

An upper surface of the cover insulating layer 14 may be an upper surface on which a semiconductor chip of a semiconductor package is disposed or a redistribution layer is disposed. Thus, in some embodiments, the cover insulating layer 14 may be a passivation layer. For example, the cover insulating layer 14 may contain an insulating material such as prepreg, and a specific composition of the cover insulating layer 14 and a specific composition of the carrier substrate 11 may be different from each other. For example, in some embodiments, the specific composition may be determined by an inorganic filler that may be mixed with an insulating material.

The cover insulating layer 14 may include a main portion 14a and a protruding structure 14b that surrounds the main portion 14a. A thickness T1+T3 of the protruding structure 14b may be greater than a thickness T3 of the main portion 14a.

The insulating material contained in the cover insulating layer 14 may be placed on the upper surface 14as of the main portion 13a of the second metal layer and a portion 14bs of the upper surface of the first metal layer 12 in a state of being slightly fluid. A portion of the insulating material may move from the upper surface 14as to a portion 14bs of the upper surface. Therefore, in some embodiments, a density of the insulating material contained in the protruding structure 14b may be slightly lower than a density of the insulating material contained in the main portion 14a.

If the difference in density between the main portion 14a and the protruding structure 14b is too large, the protruding structure 14b may include micro-voids, and the micro-voids may limit the planarization performance of the cover insulating layer 14. For example, the microvoids may be distributed close to edges of a stepped structure formed by the upper surface 14as of the main portion 13a of the second metal layer, a side surface 14ss of the main portion 13a, and the portion 14bs of the upper surface of the first metal layer 12. If the edge portion of the first metal layer 12 is also excluded, the thickness difference between the thickness T1+T2+T3 of the protrusion structure 14b and the thickness T3 of the main portion 14a may become too large. If the thickness difference is too large, the density difference between the main portion 14a and the protruding structure 14b may become larger, and the thickness T3 of the main portion 14a of the cover insulating layer 14 required to secure the planarization performance of the cover insulating layer 14 may be thicker or an additional cover insulating layer may be required.

By contrast, the method of manufacturing a semiconductor package and a semiconductor package according to some example embodiments are implemented such that a thickness difference between the thickness T1+T3 of the protruding structure 14b and the thickness T3 of the main portion 14a is less than 10 IIM. As the planarization performance of the cover insulating layer 14 may be efficiently secured, the thickness T3 of the main portion 14a of the cover insulating layer 14 may be effectively reduced. In addition, since the thickness difference exceeds 1 μm, physical robustness to the external structure (e.g., adjacent equipment) of the carrier 10a-4 may be secured.

Since the edge portion of the first metal layer 12 is not excluded, a thickness difference between the thickness T1+T3 of the protruding structure 14b and the thickness T3 of the main portion 14a may be substantially equal to the thickness T1 of the second metal layer 13. Accordingly, the thickness T1 of the second metal layer 13 may be greater than 1 μm and less than 10 μm.

The thickness T2 of the first metal layer 12 may be thicker than the thickness T1 of the second metal layer 13. For example, the thickness T2 may be about 18 μm. The fact that the thickness T2 of the first metal layer 12 is relatively thick may mean that the thickness T3 required to secure the planarization performance of the cover insulating layer 14 may vary relatively greatly depending on whether or not the edge portion of the first metal layer 12 is excluded.

For example, the thicknesses T1, T2, and T3 may be measured by analysis using at least one of a micrometer, transmission electron microscopy (TEM), atomic force microscope (AFM), scanning electron microscope (SEM), focused ion beam (FIB) optical microscope, and surface profiler, and may be defined as the average value of the sum of vertical thicknesses for each horizontal position of the corresponding layer.

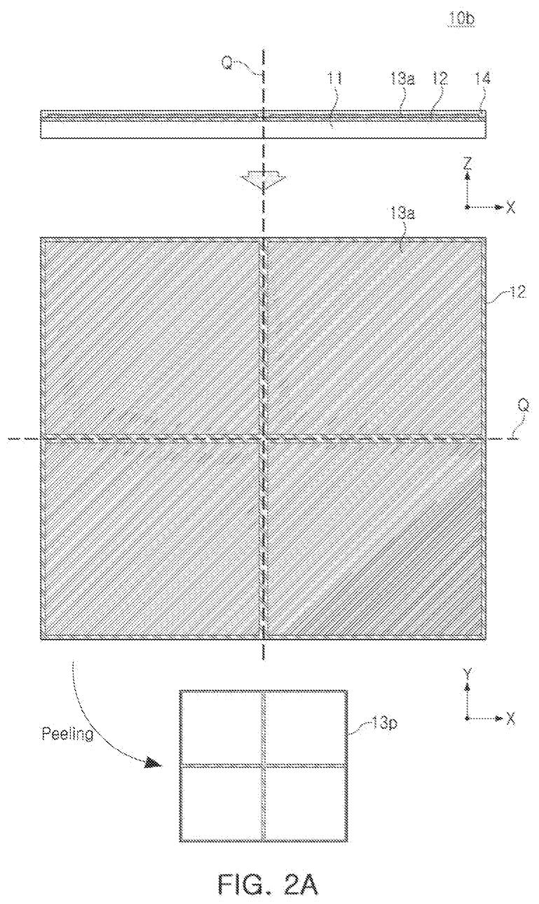

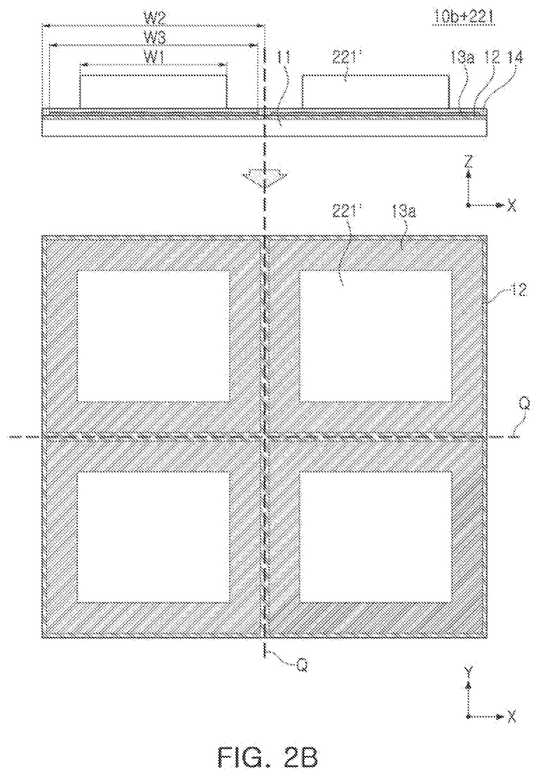

Referring to FIG. 2A, a carrier 10b may have a structure in which a plurality of carriers identical to the carriers 10a-4 illustrated in FIG. 1D are horizontally combined, and a boundary line between the plurality of carriers may correspond to the package cutting line Q. The carrier 10b may be cut along the package cutting line Q and divided into a plurality of carriers identical to the carriers 10a-4 illustrated in FIG. 1D. In the example illustrated in FIG. 2A, the carrier 10b may be cut into four carriers identical to the carriers 10a-4 in FIG. 1D.

Accordingly, the edge portion 13p of the second metal layer may have a shape surrounding each of the main portions 13a. The number of main portions 13a is not particularly limited.

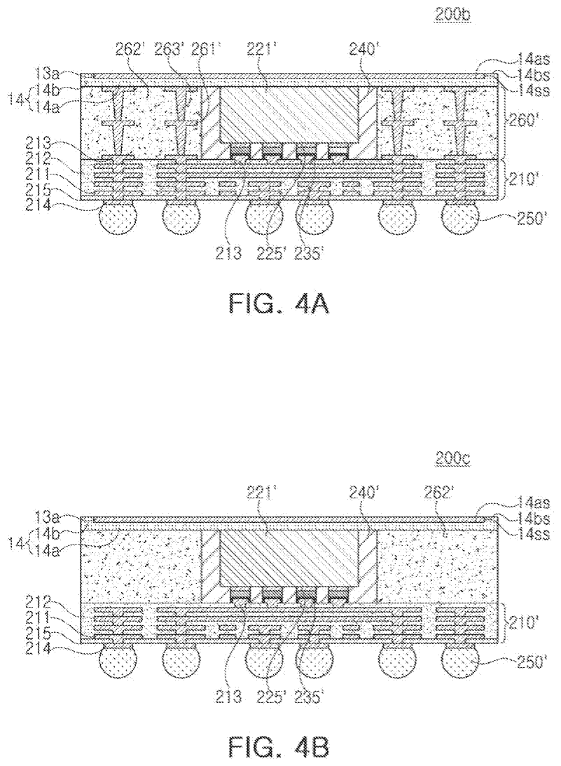

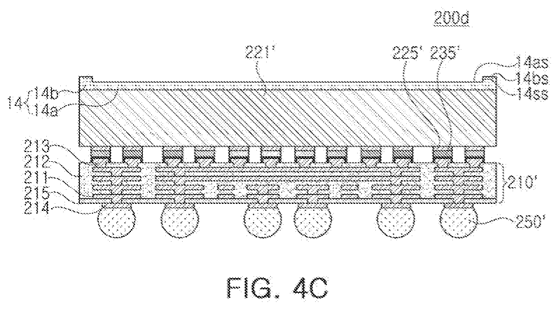

Referring to FIG. 2B, the method of manufacturing a semiconductor package according to some example embodiments may include disposing a semiconductor chip 221′ on an upper surface of a cover insulating layer 14 (step 10b+221). For example, according to the chip first method, the semiconductor chip 221′ may be disposed before a redistribution layer (211 of FIGS. 4A to 4C to be described later).

For example, the semiconductor chip 221′ may include a body portion containing a semiconductor material such as silicon (Si), germanium (Ge), or gallium arsenide (GaAs), and an element layer or an active layer disposed below the body and including an integrated circuit (IC). The semiconductor chip 221′ may include a logic semiconductor chip and/or a memory semiconductor chip. The logic semiconductor chip may be a micro-processor, and may be a Central Processing Unit (CPU), Graphic Processing Unit (GPU), Field Programmable Gate Array (FPGA), Application Processor (AP), Digital Signal Processor, Cryptographic Processor, a controller, or an application specific integrated circuit (ASIC). The memory semiconductor chip may be a volatile memory such as dynamic random access memory (DRAM) or static random access memory (SRAM) or a non-volatile memory such as flash memory.

The width W3 of each of the main portions 13a of the second metal layer may be smaller than the width W2 of the first metal layer 12 and may be wider than the width W1 of the semiconductor chip 221′. Accordingly, since the horizontal size of the finished semiconductor package may be greater than the horizontal size of the semiconductor chip 221′, the finished semiconductor package may be a fan-out package, but embodiments are not limited thereto.

The top surface of the semiconductor chip 221′ may provide an electrical connection path between the semiconductor chip 221′ and the redistribution layer (211 in FIGS. 4A to 4C), and the redistribution layer may be formed on the top surface of the semiconductor chip 221′. For example, a core member (260′ in FIGS. 4A and 4B) may horizontally surround the semiconductor chip 221′, and a redistribution layer may be formed on the upper surface of the core member and the upper surface of the semiconductor chip 221′. For example, the core member (260′ in FIGS. 4A and 4B) may be formed on the upper surface of the cover insulating layer 14 before the semiconductor chip 221′, and the semiconductor chip 221′ may be disposed in the cavity of the core member.

For example, the operation 10b+221 of arranging the semiconductor chip 221′ may include disposing the semiconductor chip 221′ such that the number of cover insulating layers 14 is one between the main portion 13a of the second metal layer and the semiconductor chip 221′. That is, in some embodiments, a single cover insulating layer 14 may be between the main portion 13a of the second metal layer and the semiconductor chip 221′. Since the thickness of the main portion 13a of the second metal layer is greater than 1 μm and less than 10 μm, the thickness requirement required to secure the planarization performance of the cover insulating layer 14 may be satisfied even if the number of cover insulating layers 14 is one.

For example, according to the chip first method, the operation 10b+221 of arranging the semiconductor chip 221′ may include disposing the semiconductor chip 221′ such that in the semiconductor chip 221′, the opposite surface (e.g., lower surface) of the surface (e.g., upper surface) electrically connected to the redistribution layer (211 in FIGS. 4A to 4C) is in contact with the cover insulating layer 14. In other words, a surface of the semiconductor chip 221′ that is opposite from the surface that is electrically connected to the redistribution layer (211 in FIGS. 4A to 4C) is in contact with the cover insulating layer 14 (see, e.g., FIGS. 4A to 4C).

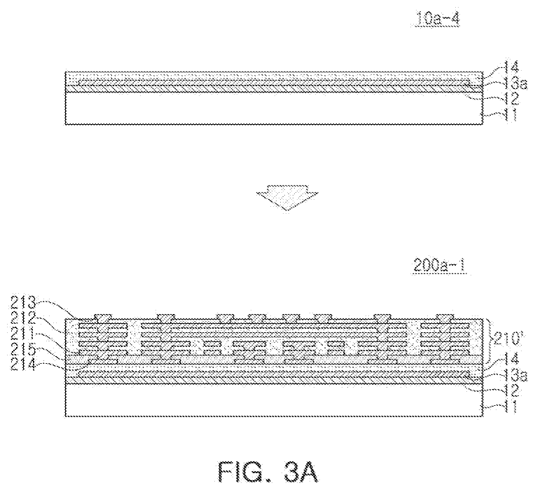

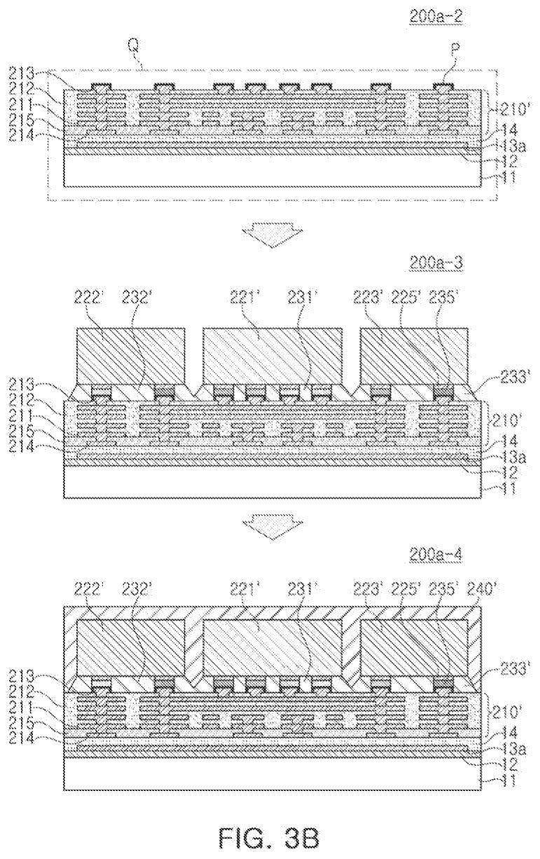

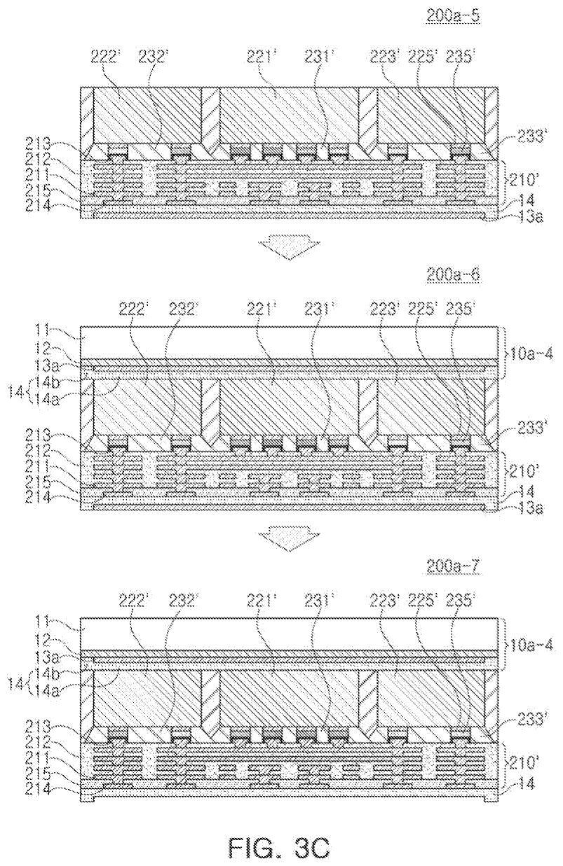

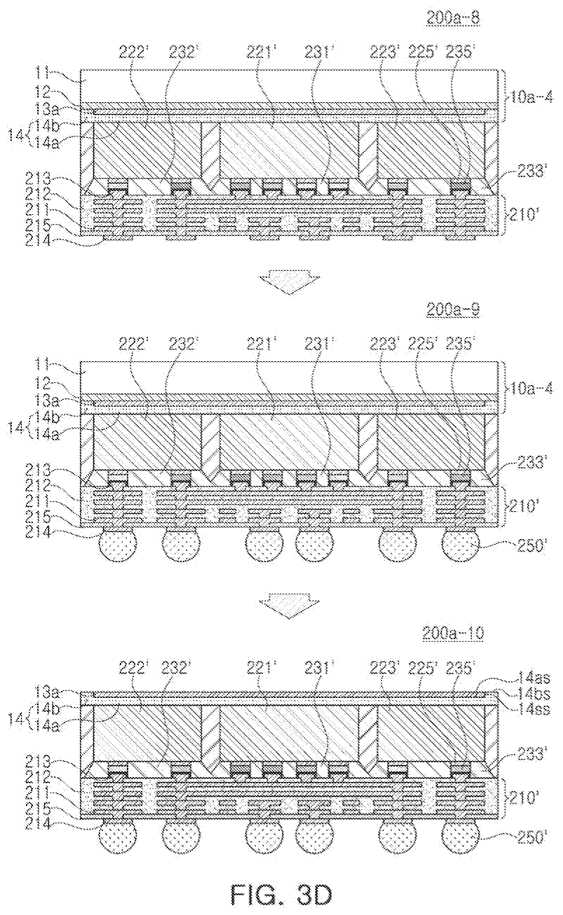

Referring to FIGS. 3A to 3D, a method of manufacturing a semiconductor package according to some example embodiments may include disposing a semiconductor chip 221′ on an upper surface of the cover insulating layer 14. For example, according to a chip last method, the redistribution layer 211 may be formed before the semiconductor chip 221′. In other words, the method of manufacturing a semiconductor package according to some example embodiments may include manufacturing a semiconductor package by selectively using one of the chip last method of FIGS. 3A-3D, and the chip first method of FIG. 2B.

Referring to FIG. 3A, the semiconductor package 200a-1 in the first state may have a redistribution structure 210′ in which redistribution layers 211 and interlayer insulating layers 212 are alternately stacked is disposed on the upper surface of the cover insulating layer 14. The interlayer vias 213 may vertically connect the redistribution layers 211 and pass through at least a portion of the interlayer insulating layers 212.

In some embodiments, the interlayer insulating layers 212 may include an insulating material, and for example, may include a thermosetting resin such as epoxy resin or a thermoplastic resin such as polyimide may be included. For example, in some embodiments, the interlayer insulating layers 212 may include a photosensitive insulating material such as a Photo Imageable Dielectric (PID) resin. In some embodiments, the interlayer insulating layers 212 may include a resin mixed with an inorganic filler, for example, Ajinomoto Build-up Film (ABF). In some embodiments, the interlayer insulating layers 212 may include prepreg, flame retardant (FR-4), or bismaleimide triazine (BT). In some embodiments, the interlayer insulating layers 212 may include the same or different materials, and the boundary therebetween may not be distinguished depending on the material and process forming each layer.

The redistribution layers 211 and the interlayer vias 213 may form an electrical path. The redistribution layers 211 may be arranged in a line shape on the x-y plane, and the interlayer vias 213 may have a cylindrical shape with side surfaces that are inclined toward the bottom or top and become narrow in width. The interlayer vias 213 are illustrated as a filled via structure in which the inside is completely filled with a conductive material, but is not limited thereto. For example, the interlayer vias 213 may have a conformal via shape in which a metal material is formed along an inner wall of the via hole. The redistribution layers 211 and the interlayer vias 213 may include a conductive material, for example, copper (Cu), aluminum (Al), silver (Ag), tin (Sn), gold (Au), nickel (Ni), lead (Pb), titanium (Ti), or alloys thereof.

Referring to FIG. 3B, the semiconductor package 200a-2 in the second state may have a structure in which a pad P is formed on an upper surface of a redistribution structure 210′. The pad P may be electrically connected to the redistribution layers 211. Pad P may be formed in a similar manner to UBMs 214 and may contain a similar material, but embodiments are not limited thereto.

Referring to FIG. 3B, the semiconductor package 200a-3 in the third state may have a structure in which at least one of the semiconductor chips 221′, 222′, and 223′ is disposed on the upper surface of the redistribution structure 210′ by a flip-chip bonding method. For example, bumps 235′ may contact and be disposed on the pad P, and may contact and be disposed on connection pads 225′ of the semiconductor chips 221′,222′, and 223′. For example, in some embodiments, the connection pad 225′ may include a conductive material such as tungsten (W), aluminum (Al), or copper (Cu), may be a pad of a bare chip, for example, an aluminum (Al) pad, and according to embodiments, may be a pad of a packaged chip, for example, a copper (Cu) pad.

The non-conductive film layers 231′,232′, and 233′ may be disposed between the redistribution structure 210′ and the semiconductor chips 221′,222′, and 223′ to surround the bumps 235′. The non-conductive film layers 231′,232′, and 233′ may be referred to as underfill layers, and may contain a non-conductive polymer. For example, in some embodiments, the non-conductive film layers 231′,232′, and 233′ may contain and may contain a non-conductive paste (NCP).

Referring to FIG. 3B, the semiconductor package 200a-4 in the fourth state may have a structure in which a sealing material 240′ for sealing the semiconductor chips 221′,222′, and 223′ on the upper surface of the redistribution structure 210′ is disposed on the upper surface of the redistribution structure 210′. The encapsulant 240′ may contain a molding material such as an Epoxy Molding Compound (EMC), but embodiments are not limited thereto.

According to some embodiments, some of the semiconductor chips 222′ and 223′ may be omitted, and the encapsulant 240′ may fill a space occupied by some of the semiconductor chips 222′ and 223′. In some embodiments, the core member 260′ illustrated in FIGS. 4A and 4B may occupy a space occupied by some of the semiconductor chips 222′ and 223′.

Referring to FIG. 3C, the semiconductor package 200a-5 in the fifth state may have a structure in which the carrier substrate and the first metal layer are detached from the main portion 13a of the second metal layer and the cover insulating layer 14. A method of manufacturing a semiconductor package according to some example embodiments may further include detaching the carrier substrate and the first metal layer from the main portion 13a of the second metal layer and the cover insulating layer 14 after the semiconductor chip 221′ is disposed.

Referring to FIG. 3C, the semiconductor package 200a-5 in the fifth state may have a structure in which an upper portion of an encapsulant 240′ is polished such that the upper surfaces of the semiconductor chips 221′,222′, and 223′ are exposed. The operation of arranging the semiconductor chip 221′ of the method of manufacturing a semiconductor package according to some example embodiments may include disposing the semiconductor chip 221′ such that the surface (e.g., upper surface) opposite to the surface (e.g., lower surface) of the semiconductor chip 221′ electrically connected to the redistribution layer 211 contacts the cover insulating layer (14 of the semiconductor package 200a-6 in the sixth state).

Referring to FIG. 3C, the semiconductor package 200a-6 in the sixth state may have a structure in which the carriers 10a-4 of FIG. 1D are disposed on the upper surfaces of the semiconductor chips 221′,222′, and 223′. For example, according to some embodiments, the carriers 10a-4 of FIG. 1D may not only provide a space in which the semiconductor chip 221′ of FIG. 2B is disposed, but also provide a space in which a structure in which the semiconductor chip 221′ is coupled to the redistribution structure 210′ is disposed.

Referring to FIG. 3C, the semiconductor package 200a-7 in the seventh state may have a structure in which the main portion 13a of the second metal layer is removed. For example, the main portion 13a of the second metal layer may be etched by a copper etching solution or gas.

Referring to FIG. 3D, the semiconductor packages 200a-8 in the eighth state may have a structure in which the cover insulating layer is removed and a portion of the lowermost insulating layer 215 is removed. The lowermost insulating layer 215 may be a solder resist, but is not limited thereto.

Referring to FIG. 3D, the semiconductor packages 200a-9 in the ninth state may have a structure in which bumps 250′ are contacted and disposed on the lower surface of the UBM 214.

The bumps 250′ are electrically connected to the redistribution layers 211 and may be arranged on one surface (e.g., the lower surface) of the redistribution structure 210′. For example, the bumps 250′ may have a ball or column shape, and may include a solder containing tin (Sn) or an alloy (Sn—Ag—Cu) containing tin (Sn). The bumps 250′ may have a relatively low melting point compared to other metal materials, and may thus be connected and fixed on the UBM 214 by a thermal compression bonding (TCB) process or a reflow process.

Under Bump Metallurgy (UBM) 214 may be electrically connected between the interlayer vias 213 and the bumps 250′, and the bumps 250′ may be arranged to face each other in a stacking direction (e.g., a vertical direction) of the redistribution structure 210′. For example, the UBMs 214 may provide a sufficiently wide bottom surface such that some of the material of the bumps 250′ does not leak sideways when the bumps 250′ are formed. The bumps 250′ may contact the wide lower surfaces of the UBMs 214. Accordingly, the UBMs 214 may be advantageous in reducing contact resistance between the bumps 250′ and the redistribution layers 211.

Referring to FIG. 3D, the semiconductor package 200a-10 in the 10th state may have a structure in which the carrier substrate and the first metal layer are detached from the main portion 13a of the second metal layer and the cover insulating layer 14. A method of manufacturing a semiconductor package according to some example embodiments may further include detaching the carrier substrate and the first metal layer from the main portion 13a of the second metal layer and the cover insulating layer 14 after the semiconductor chip 221′ is disposed.

Referring to FIGS. 4A, 4B, and 4C, semiconductor packages 200b, 200c, and 200d according to some example embodiments may include a semiconductor chip 221′ electrically connected to the redistribution layer 211, and a cover insulating layer 14 disposed on a surface (e.g., upper surface) opposite to the surface (e.g., lower surface) of the semiconductor chip 221′ facing the redistribution layer 211. The semiconductor packages 200b, 200c, and 200d may be manufactured by at least a part of the semiconductor package manufacturing method illustrated in FIGS. 3A to 3D, but embodiments are not limited thereto.

The cover insulating layer 14 may not provide an electrical connection path between a surface facing the semiconductor chip 221′ (e.g., lower surface) and an opposite surface (e.g., upper surface) of the cover insulating layer 14. Therefore, the role of the cover insulating layer 14 (e.g., planarization, provision of the surface of a semiconductor package) may be different from the role of the interlayer insulating layer 212 (e.g., provision of insulation between redistribution layers and arrangement space for redistribution layers).

The cover insulating layer 14 may include a main portion 14a disposed on the upper surface of the semiconductor chip 221′ and a protruding structure 14b surrounding the main portion 14a. The protruding structure 14b may protrude from a surface (e.g., an upper surface) opposite to a surface (e.g., a lower surface) facing the semiconductor chip 221′ in the cover insulating layer 14, and may be positioned so as to surround the semiconductor chip 221′ from a viewpoint facing the semiconductor chip 221′ (e.g., in a vertical direction). The protruding length of the protruding structure 14b may be greater than 1 μm and less than 10 μM.

Accordingly, the thickness of the main portion 14a of the cover insulating layer 14 may be reduced, and the number of cover insulating layers 14 may be one between the surface facing the semiconductor chip 221′ (e.g., lower surface) and the opposite surface (e.g., upper surface) of the cover insulating layer 14. That is, a single cover insulating layer 14 may be between the surface facing the semiconductor chip 221′ (e.g., lower surface) and the opposite surface (e.g., upper surface) of the cover insulating layer 14.

Since the cover insulating layer 14 may provide surfaces of the semiconductor packages 200a and 200b and may protect the semiconductor packages 200a and 200b from external impact, and the protruding structure 14b may be exposed to air in a protruding direction (e.g., upper surface).

Referring to FIGS. 4A and 4B, semiconductor packages 200b and 200c according to some example embodiments may further include the main portion of the second metal layer disposed on the surface (e.g., upper surface) opposite to the surface (e.g., lower surface) facing the semiconductor chip 221′ in the cover insulating layer 14 and surrounded by the protruding structure 14b (13a). The thickness of the main portion 13a of the second metal layer may be greater than 1 μm and less than 10 μm. For example, the main portion 13a of the second metal layer may be used or acted as a heat dissipation path of the semiconductor chip 221′ or used as a shielding wall against electromagnetic noise.

Referring to FIGS. 4A and 4B, the semiconductor packages 200b and 200c may further include a core member 260′ surrounding the semiconductor chip 221′ and containing an insulating material.

For example, since a core insulation layer 262′ of the core member 260′ may have greater thickness and/or rigidity than one of interlayer insulating layers 212, the core insulation layer 262′ may reduce a possibility of warpage of the redistribution structure 210. For example, the core insulation layer 262′ may be similar to a core disposed in a center of a printed circuit board, and the core member 260′ may have a structure resulting from a PLP structure, but is not limited thereto. Since the core member 260′ surrounding the semiconductor chip 221′ may be disposed to overlap the redistribution structure 210 in a vertical direction, the semiconductor packages 200b and 200c may have a FO-PLP structure.

Referring to FIG. 4A, the core member 260′ may further include a core wiring layer 261′ and/or a core via 263′ as well as a core insulation layer 262′. For example, the core wiring layer 261′ may be disposed on the upper and/or lower surfaces of the core insulating layer 262′, and overall, may be implemented larger than the redistribution layer 211 (e.g., wider line width, longer pitch), and may be implemented in a manner similar to a method of forming a wiring of a printed circuit board. The core via 263′ may vertically penetrate the core insulating layer 262′, may be connected to the core wiring layer 261′, and may be implemented to be larger than the interlayer via 213 as a whole.

Referring to FIG. 4C, a semiconductor package 200d according to some example embodiments may have a structure in which the horizontal size of the redistribution structure 210′ and the horizontal size of the semiconductor chip 221′ are substantially the same, and therefore, may have a fan-in structure.

As set forth above, a method of manufacturing a semiconductor package and a semiconductor package according to some example embodiments may improve efficiency related to a carrier implemented to be robust against physical conditions with respect to an external structure (e.g., adjacent equipment).

While example embodiments have been illustrated and described above, it will be apparent to those skilled in the art that modifications and variations could be made without departing from the scope of the present disclosure as defined by the appended claims.

What is claimed is:

1. A method of manufacturing a semiconductor package, the method comprising:
applying a cutter to a boundary between a main portion of a second metal layer and an edge portion of the second metal layer that surrounds the main portion, the second metal layer being on an upper surface of a first metal layer disposed on an upper surface of a carrier substrate;
peeling the edge portion of the second metal layer from the first metal layer;
forming a cover insulating layer on an upper surface of the main portion of the second metal layer; and
disposing a semiconductor chip on an upper surface of the cover insulating layer.

2. The method of claim 1, wherein the first metal layer is not divided into a plurality of portions by the cutter.

3. The method of claim 1, wherein the cutter comprises a laser and the applying includes irradiating the laser onto the boundary.

4. The method of claim 1, wherein the peeling includes pulling the edge portion of the second metal layer from the first metal layer or applying a force to the edge portion of the second metal layer in a direction different from a direction facing the first metal layer.

5. The method of claim 1, wherein the disposing of the semiconductor chip includes disposing the semiconductor chip such that a number of the cover insulating layer is one between the main portion of the second metal layer and the semiconductor chip.

6. The method of claim 1, wherein the disposing of the semiconductor chip includes disposing the semiconductor chip such that a first surface of the semiconductor chip opposite to a second surface of the semiconductor chip that is electrically connected to a redistribution layer is in contact with the cover insulating layer.

7. The method of claim 1, further comprising, after the semiconductor chip is disposed, detaching the carrier substrate and the first metal layer from the main portion of the second metal layer and the cover insulating layer.

8. The method of claim 1, wherein the carrier substrate contains a prepreg.

9. The method of claim 1, wherein each of the first metal layer and the second metal layer is a single metal layer containing copper.

10. The method of claim 1, wherein a thickness of the second metal layer is greater than 1 μm and less than 10 μm.

11. A method of manufacturing a semiconductor package, the method comprising:
exposing a portion of a first metal layer by removing an edge portion of a second metal layer that surrounds a main portion of the second metal layer, the second metal layer being on an upper surface of the first metal layer disposed on an upper surface of a carrier substrate;
forming a cover insulating layer on an upper surface of the main portion of the second metal layer; and
disposing a semiconductor chip on an upper surface of the cover insulating layer,
wherein a thickness of the second metal layer is greater than 1 μm and less than 10 μm.

12. The method of claim 11, wherein each of the first metal layer and the second metal layer is a single metal layer containing copper.

13. The method of claim 12, wherein the carrier substrate contains a prepreg.

14. The method of claim 13, wherein the disposing of the semiconductor chip includes disposing the semiconductor chip such that a number of the cover insulating layer is one between the main portion of the second metal layer and the semiconductor chip.

15. The method of claim 14, wherein the disposing of the semiconductor chip includes disposing the semiconductor chip such that a first surface of the semiconductor chip opposite to a second surface of the semiconductor chip that is electrically connected to a redistribution layer is in contact with the cover insulating layer.

16. A semiconductor package comprising:
a semiconductor chip electrically connected to a redistribution layer; and
a cover insulating layer disposed on a first surface of the semiconductor chip opposite to a second surface of the semiconductor chip that faces the redistribution layer,
wherein the cover insulating layer does not provide an electrical connection path between a facing surface of the cover insulating layer that faces the semiconductor chip and an opposite surface of the cover insulating layer that is opposite to the facing surface,
the opposite surface of the cover insulating layer has a protruding structure that surrounds the semiconductor chip from a viewpoint facing the semiconductor chip, and
a protruding length of the protruding structure is greater than 1 μm and less than 10 μm.

17. The semiconductor package of claim 16, wherein a number of the cover insulating layer is one between the facing surface and the opposite surface of the cover insulating layer.

18. The semiconductor package of claim 17, wherein the protruding structure is exposed to air in a protruding direction.

19. The semiconductor package of claim 18, further comprising a metal layer disposed on a portion of the opposite surface of the cover insulating layer surrounded by the protruding structure,
wherein a thickness of the metal layer is greater than 1 μm and less than 10 μm.

20. The semiconductor package of claim 16, further comprising:
a core member surrounding the semiconductor chip and containing an insulating material; and
a redistribution structure in which the redistribution layer and an interlayer insulating layer are alternately stacked,
wherein a surface of the redistribution structure that faces the semiconductor chip is overlapped with the semiconductor chip and the core member.
